(19) United States
(12) Patent Application Publication
(10) Pub. No.: US 2025/0232347 A1
(43) Pub. Date: Jul. 17, 2025

(54) SYSTEMS AND METHODS FOR DETERMINING DECORATIVE TILE CONFIGURATIONS BASED ON ACOUSTIC CHARACTERISTICS

(71) Applicant: FeltRight, LLC, Draper, UT (US)

(72) Inventors: Raymond Talley GOODSON, Salt Lake City, UT (US); Jordan Nyle GARN, Orem, UT (US)

(21) Appl. No.: 19/022,702

(22) Filed: Jan. 15, 2025

Related U.S. Application Data
(60) Provisional application No. 63/621,502, filed on Jan. 16, 2024.

(51) Int. Cl. G06Q 30/0601; G06F 3/0482; G06F 3/04845

(52) U.S. Cl. CPC G06Q 30/0621; G06F 3/0482; G06F 3/04845

(57) ABSTRACT

A system for determining decorative tile configurations is configurable to: (i) present, at a user interface, a room use prompt; (ii) receive user input directed to the room use prompt indicating one or more room use parameters associated with a physical room; (iii) present, at the user interface, a room characteristics prompt; (iv) receive additional user input directed to the room characteristics prompt indicating a set of room characteristics associated with the physical room, wherein the set of room characteristics comprises room size and one or more of: existing soft surface coverage, open entryways, or plush furniture characteristics; (v) generate one or more target coverage areas for a set of decorative tiles installable within the physical room by using the one or more room use parameters and the set of room characteristics as inputs; and (vi) present the one or more target coverage areas on the user interface.

### CROSS-REFERENCE TO RELATED APPLICATIONS

This application claims priority to U.S. Provisional Patent Application No. 63/621,502, Filed on Jan. 16, 2024, and entitled “SYSTEMS AND METHODS FOR DETERMINING DECORATIVE TILE CONFIGURATIONS BASED ON ACOUSTIC CHARACTERISTICS”, the entirety of which is incorporated herein by reference for all purposes.

### BACKGROUND

People often decorate their walls with canvas art, framed art, photo frames, decorative tiles, and more. However, most wall décor is not customizable. For example, commercially available decorative tile patterns are often fixed on a backing mesh based on a predesigned pattern, and a customer cannot rearrange those tiles. Further, the size of such a decorative tile pattern is limited.

The subject matter claimed herein is not limited to embodiments that solve any challenges or that operate only in environments such as those described above. Rather, this background is only provided to illustrate one exemplary technology area where some embodiments described herein may be practiced.

### BRIEF DESCRIPTION OF THE DRAWINGS

In order to describe the manner in which the above-recited and other advantages and features can be obtained, a more particular description of the subject matter briefly described above will be rendered by reference to specific embodiments which are illustrated in the appended drawings. Understanding that these drawings depict only typical embodiments and are not therefore to be considered to be limiting in scope, embodiments will be described and explained with additional specificity and detail through the use of the accompanying drawings in which:

FIG. 1 illustrates an example environment in which the principles described herein may be implemented;

FIG. 2 illustrates an example of a graphical user interface that allows a user to browse premade designs or create their own design;

FIG. 3A illustrates another example of a graphical user interface that allows a user to choose from premade designs or start from scratch;

FIGS. 3B, 3C, and 3D illustrate examples of graphical user interfaces that allow a user to choose a grid and dimensions for a design;

FIGS. 4A and 4B illustrate examples of graphical user interfaces of design studios that include a design area and a user selection area;

FIGS. 5A, 5B, 5C, 5D, and 5E illustrate enlarged views of subareas of the user selection area of the design studio of FIG. 4A;

FIG. 5F illustrates an example preview of a design from the design area of the design studio of FIG. 4A;

FIG. 5G illustrates example instructions generated based on the design from the design area of the design studio of FIG. 4A;

FIG. 5H illustrates an enlarged view of a subarea of the user selection area of the design studio of FIG. 4A; and

FIG. 6 illustrates an example graphical user interface for determining a target coverage area for a decorative tile design.

FIG. 7 illustrates an example graphical user interface of a component of the design studio of FIG. 4A.

FIGS. 8 and 9 illustrate example flow diagrams depicting acts associated with the disclosed subject matter.

### DETAILED DESCRIPTION

Embodiments described herein are related to a system (e.g., a server computing system, such as a web server), a method, and/or a computer program product (e.g., computer-readable recording media). The system is configured to display a graphical user interface of a design studio at a client computing system for a user at the client computing system to generate their own custom tile pattern designs. These designs may be realized by any type of tiles, including (but not limited to) felt tiles, ceramic tiles, stone tiles, wood tiles, bamboo tiles, and/or vinyl tiles. In some embodiments, the system may include a portal for customer users and a portal for store employees, and the system may link the tiles used in the customer's design to the available products of one or more tile stores. As such, the user can generate their own creative design and purchase the tiles used in the design from the one or more tile stores conveniently.

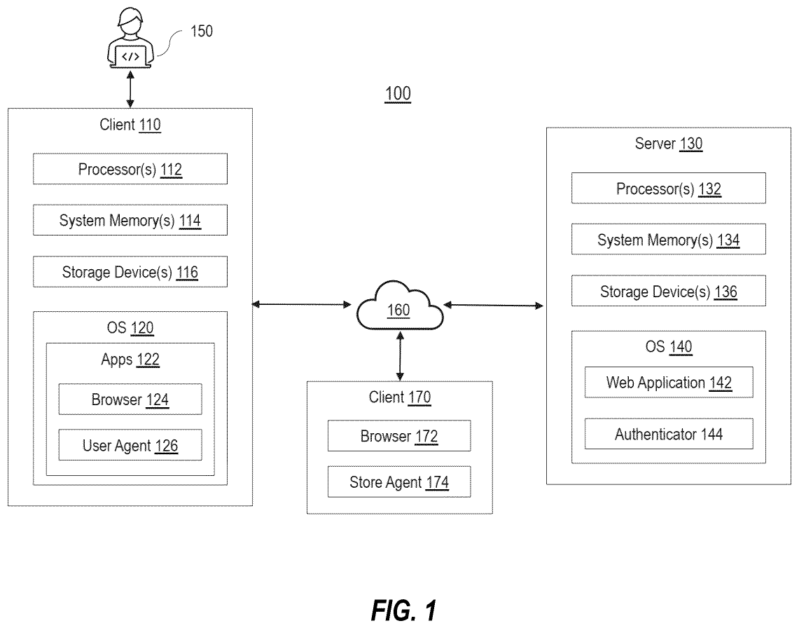

FIG. 1 illustrates an example environment 100 that includes a server computing system 130, a first client computing system 110, and a second client computing system 170, configured to communicate with each other via a network 160. The network 160 may be the Internet. The first client computing system 110 may be a personal computer, a laptop, a mobile device, or any type of device of a user 150. The first client computing system 110 may include one or more processors 112, one or more system memories 114, and/or one or more storage devices 116. In some embodiments, the client computing system 110 may also include an operating system 120 installed in the storage devices 116 and loaded into the system memories 114. The first client computing system 110 may also include one or more applications installed in the storage devices 116 and loaded in the system memories 114. In some embodiments, one or more applications 122 include a browser 124 configured to execute a web application 142 hosted at the server computing system 130. In some embodiments, the one or more applications 122 includes a user agent application 126 configured to allow a user to interact with the server computing system 130 in a predetermined manner.

The server computing system 130 may be a web server that hosts a web application 142. As illustrated, the server computing system 130 may include one or more processors 132, one or more system memories 134, and/or one or more storage devices 136. The server computing system 130 may also include an operating system 140 installed in the one or more storage devices 136 and loaded in the system memories 134. In some embodiments, in addition to the web application 142, the server computing system 130 also includes or is coupled to an authenticator 144 configured to register new users and/or authenticate existing users.

Further, the server computing system 130 is also configured to display a graphical user interface of a design studio at the first client computing system 110. In some embodiments, the graphical user interface may be displayed in the browser 124 of the first client computing system 110. In some embodiments, the graphical user interface may be displayed in the user agent application 126 of the first client computing system 110. In some implementations, the user can use the graphical user interface to generate a custom decorative tile design/pattern and order the tiles used in the custom design from a store.

Further, as shown in FIG. 1, there may also be a second client computing system 170. Similar to the first client computing system 110, the second client computing system 170 of FIG. 1 also includes one or more processors, one or more system memories, storage devices, and an operating system (not shown). However, unlike the first client computing system 110, the second client computing system 170 of FIG. 1 is configured to allow a store representative to access records associated with orders made by the users. In some embodiments, the store representative can use the browser 172 to access a store-side web portal and/or use a store agent application 174 to access records associated with orders made by the users. In some embodiments, when the user makes an order via the first client computing system 110, the server computing system 130 causes the second client computing system 170 to generate a notification and/or displays the order summary to the store representative, such that the store representative can assemble a tile kit based on the order summary.

Note, even though FIG. 1 only shows one computing system that is associated with a customer user and one computing system that is associated with a tile store, in reality, there may be many different customer users using many different client computing systems, and there may be many different store representatives for a particular tile store or for many different tile stores using many different client computing systems. All the different client computing systems associated with customer users and store representatives may be configured to communicate with the server computing system 130. As used herein, a “system” can refer to any of the first client computing system 110, the second client computing system 170, the server computing system 130, combinations thereof, and/or other types of devices that include processing and storage capabilities enabling the device to carry out actions described herein.

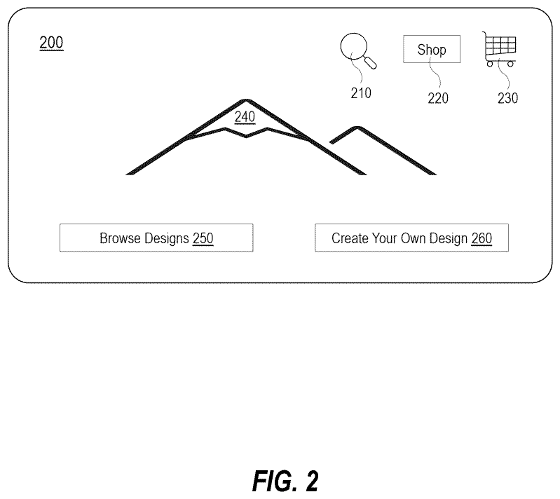

FIG. 2 illustrates an example of a graphical user interface 200 that may be displayed at the browser 124 or the user agent application 126 of the first client computing system 110. The graphical user interface 200 may include a background image 240, a search icon 210, a shop button 220, and/or a shopping cart icon 230. The background image 240 may be a popular tile pattern design. The search icon 210 may be configured to allow a user to input one or more search terms for searching the website or the application. The shop button 220 may be configured to allow a user to shop directly from an online store selling different types of tiles. The shopping cart icon 230 may indicate how many items have been placed in a shopping cart of a user. When the user clicks the shopping cart icon 230, the user may be brought to a next interface showing a list of items placed in the shopping cart.

Further, in some embodiments, the graphical user interface 200 may also include a browse designs button 250 and a create your own design button 260 (other types of selectable elements may be used). When a user clicks the browse designs button 250, the user is presented with a gallery of one or more premade designs, and the user can select a particular premade design from the gallery and modify the particular premade design based on their own desire. When the user clicks the create your own design button 260, a new decorative tile design is generated, and the user can build their own decorative tile design.

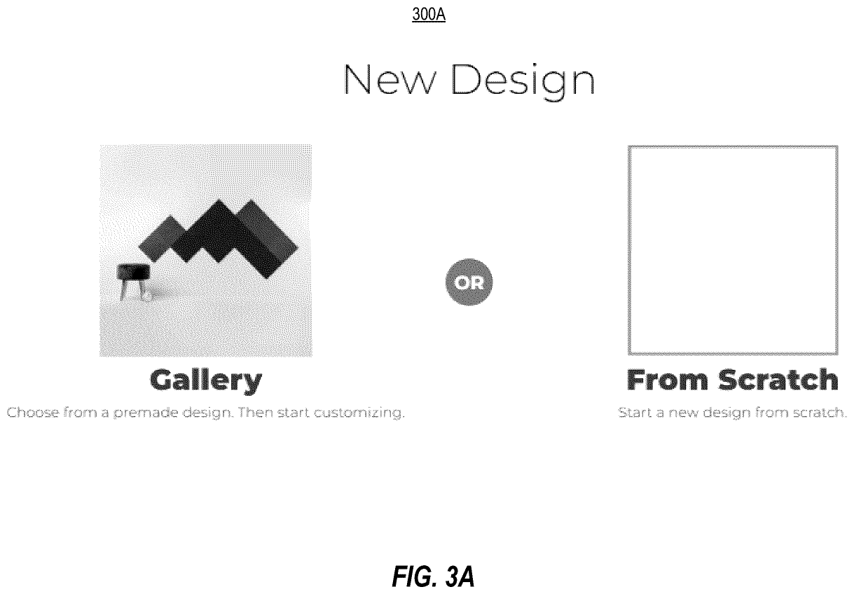

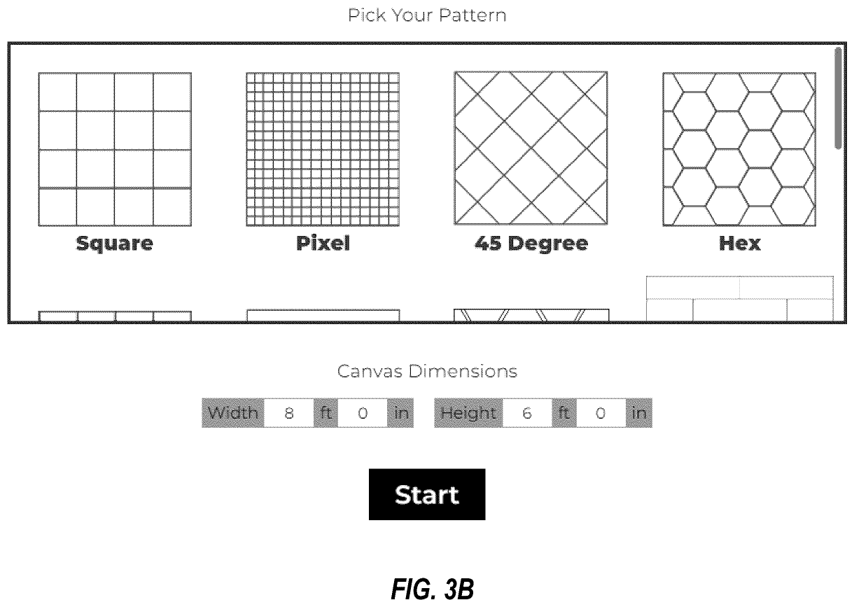

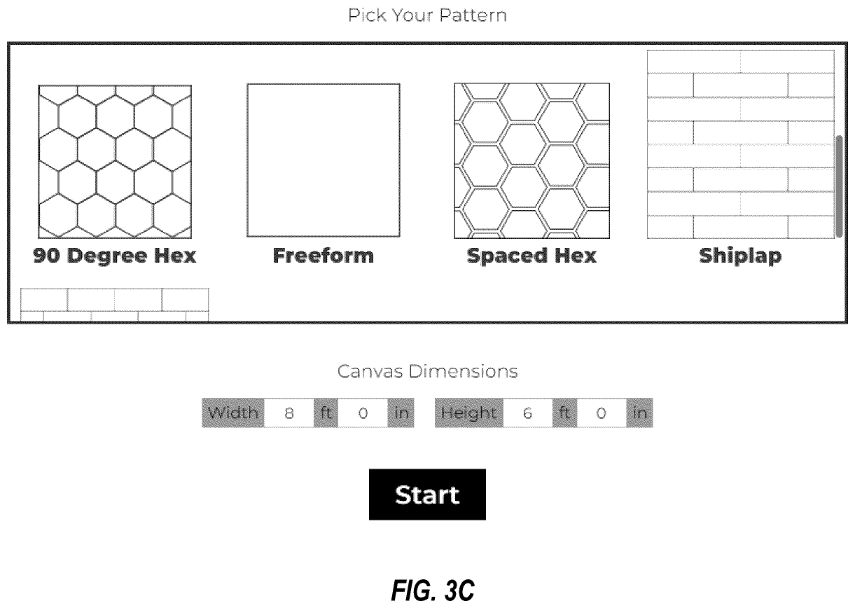

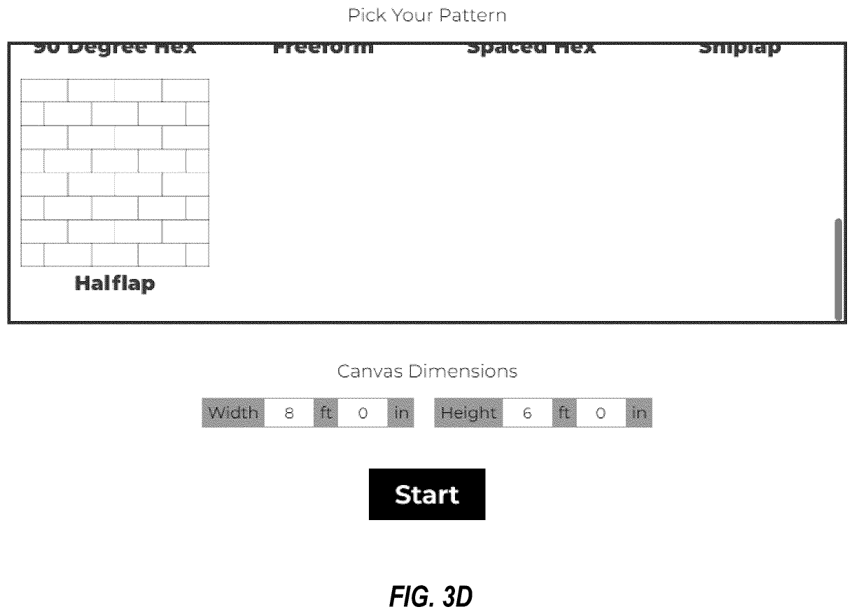

FIG. 3A illustrates another example of a graphical user interface 300A showing that a user is allowed to choose from a gallery of one or more premade designs (on the left) or choosing to start a new design from scratch (on the right). Once the user selects a premade design or starting a new design from scratch, a graphical user interface of a design studio may be displayed at the first client computing system 110.

FIGS. 3B, 3C, and 3D illustrate examples of graphical user interfaces 300B, 300C, and 300D, respectively, showing instances in which a user is able to choose from an orientation of grids or guides that are to be displayed in the design area of the design studio. Graphical user interface 300B of FIG. 3B illustrates example background grids or guide patterns that include a square grid, a pixel grid (e.g., with smaller squares), a 45-degree grid, and a hex grid. Graphical user interface 300C of FIG. 3C illustrates example background grids or guide patterns that include a 90-degree hex grid, a freeform background (e.g., with no grid, enabling free-form designing by users), a spaced hex grid, and a shiplap grid. Graphical user interface 300D of FIG. 3D illustrates an example background grid or guide pattern that includes a halflap pattern. Other types of grids or guide patterns may be utilized in accordance with the disclosed subject matter.

In some embodiments, the user is also allowed to choose dimensions of the design, including a width and a height, depending on the needs of the user (as shown in the “Canvas Dimensions” section of graphical user interfaces 300B, 300C, and 300D of FIGS. 3B, 3C, and 3D, respectively). For example, if the user intends to place a design in a wall having a dimension of 70 inches×40 inches, the user can enter corresponding dimensions in the “Canvas Dimensions” section of graphical user interfaces 300B, 300C, or 300D to cause the design area of the design studio to correspond to the wall dimensions.

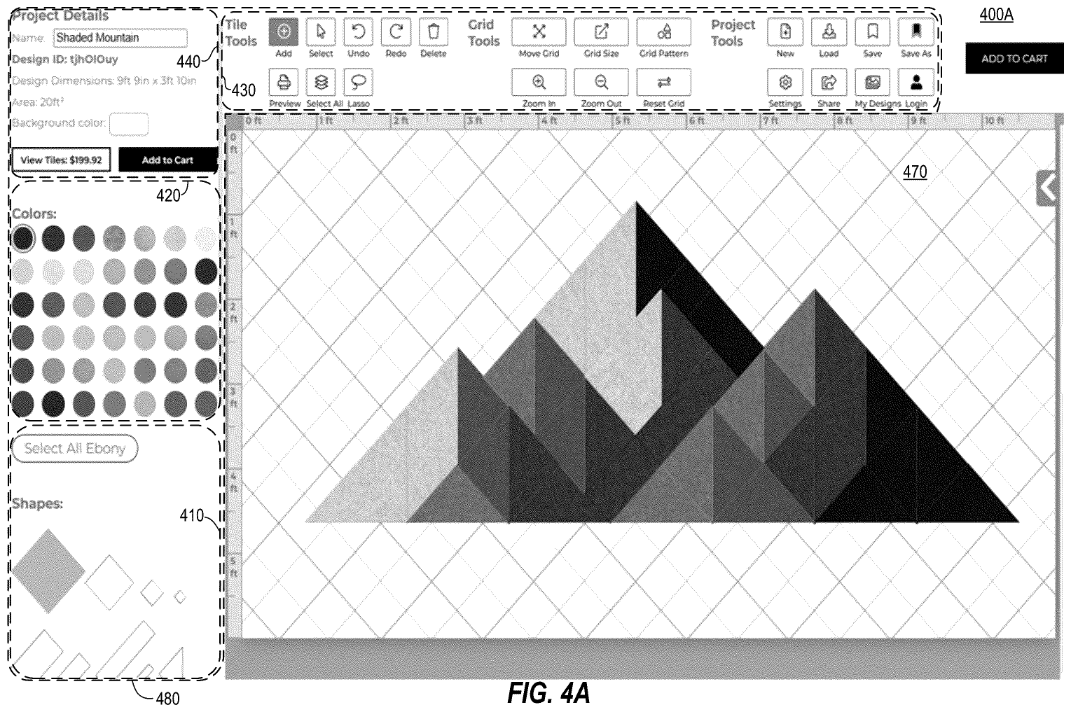

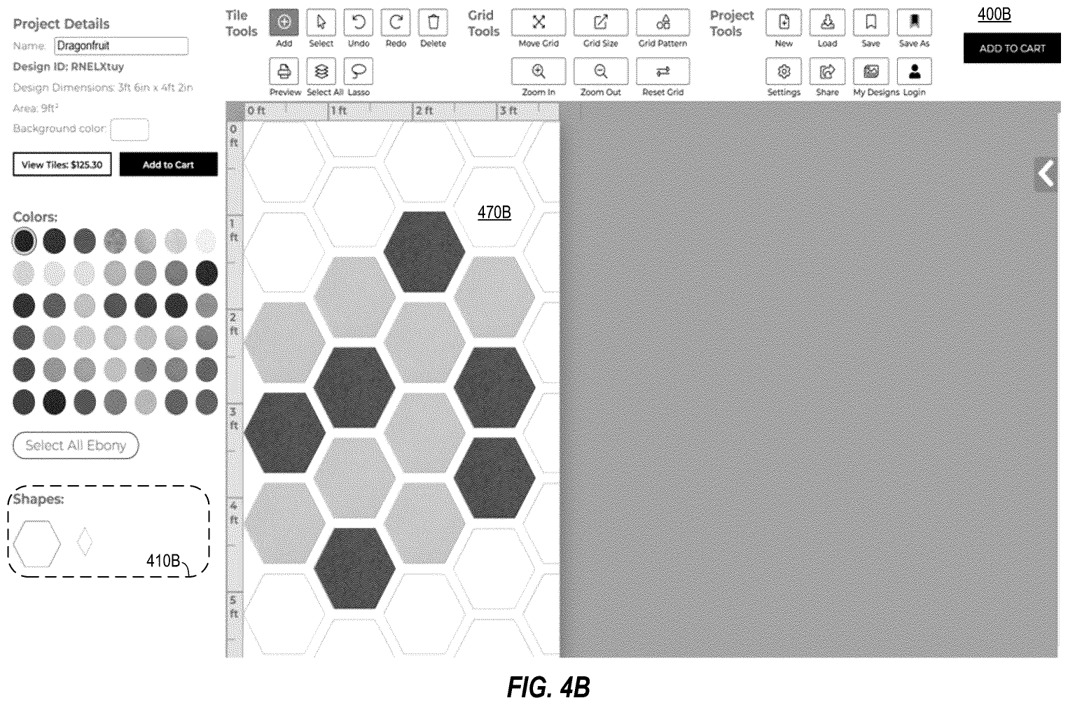

FIG. 4A illustrates an example of a graphical user interface of a design studio 400A. The graphical user interface of the design studio 400A includes a design area 470 and a user selection area 480. In the example of FIG. 4A, the design area 470 has a plurality of grids in the format of a 45-degree grid pattern. As noted above with reference to FIGS. 3B through 3D, other types of grids/patterns for the design area 470 may be utilized (see also FIG. 4B). The design area 470 can act as a virtual canvas on which users may place, arrange, and configure virtual representations of decorative tiles to facilitate creation of a decorative tile design. In the example of FIG. 4A, the design area 470 includes decorative tiles with various sizes, shapes, colors, orientations, and patterns/engravings, forming a decorative tile design.

The user selection area 480 of the design studio 400A includes various tools, controls, options, and/or other selectable elements that, when selected, trigger functions related to creation of a decorative tile design. In the example of FIG. 4A, the user selection area 480 includes one or more subareas 410, 420, 430, and 440, each of which include various selectable elements for facilitating creation of a decorative tile design. The subareas 410, 420, 430, and 440 are arbitrarily defined for ease of description, and the particular designation of the subareas does not limit the scope of the disclosed subject matter.

Using the design area 470 and the user selection area 480, a user may create a decorative tile design. For instance, a system may display the design studio 400A on a user interface (e.g., a client computing system, or other device). The user may provide user inputs at the user interface directed to the design area 470 and/or the user selection area 480 to create a decorative tile design. For instance, the user selection area 480 can include selectable attributes such as decorative tile shapes (e.g., in subarea 410), decorative tile colors (e.g., in subarea 420), decorative tile orientations (e.g., accessible via subarea 410), decorative tile patterns/engravings, and/or others. The user may provide user input selecting one or more attributes from the user selection area 480 to define characteristics of a (virtual) decorative tile to be placed in the design area 470. The user may then provide additional user input placing the decorative tile (with the characteristics defined by the selected attribute(s) from the user selection area 480) within the design area 470.

In some instances, placement of a decorative tile within the design area 470 is affected by the grid pattern of the design area 470. For example, placing the decorative tile in the design area 470 can include identifying a grid (or fraction of a grid) of the design area 470 closest to the position of the user input/command (e.g., a mouse click or touch input) for placing the decorative tile in the design area 470. The decorative tile may then be placed in the design area 470 by snapping the positioning of the decorative tile to the identified grid (or fraction of a grid) in the design area 470.

Furthermore, in some implementations, after a (virtual) decorative tile has been placed in the design area 470, the user may effectuate modifications to the decorative tile. For instance, a user may direct user input to a decorative tile already placed within the design area 470. The user may then provide additional input directed to the user selection area 480 to select or modify attributes/characteristics of the selected decorative tile (e.g., to modify the shape, color, orientation, engraving/pattern, etc.), which may be updated/changed in real-time. Users may additionally, or alternatively, provide user input directed to the design area 470 after selecting a decorative tile from the design area 470 to reposition or move the selected decorative tile within the design area 470.

A user may provide user inputs such as those described above (and hereinafter) until the decorative tile design is complete. Additional details related to utilizing a design studio 400A to create a decorative tile design will be described hereinbelow, with reference to the various subareas represented in the design studio 400A FIG. 4A.

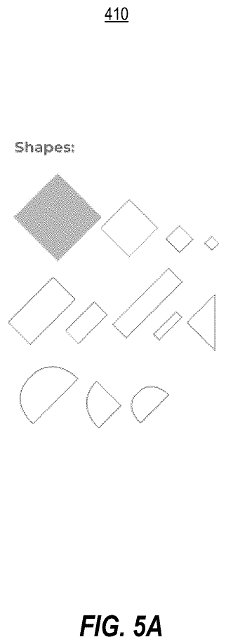

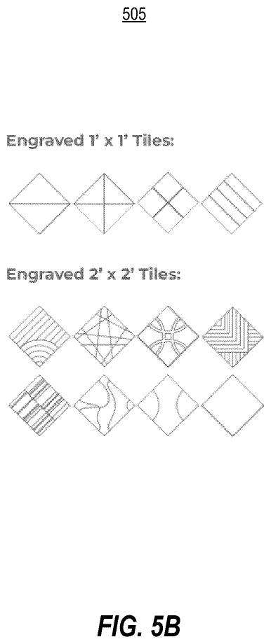

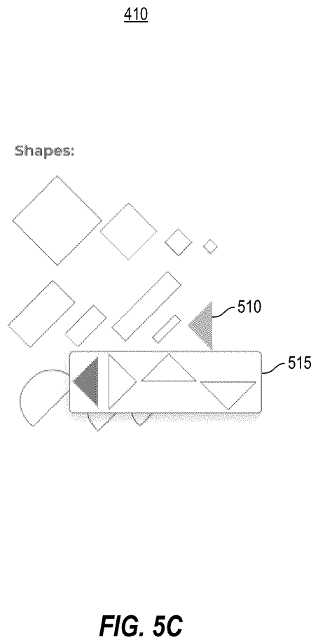

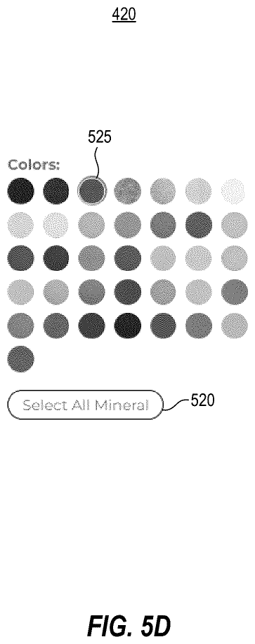

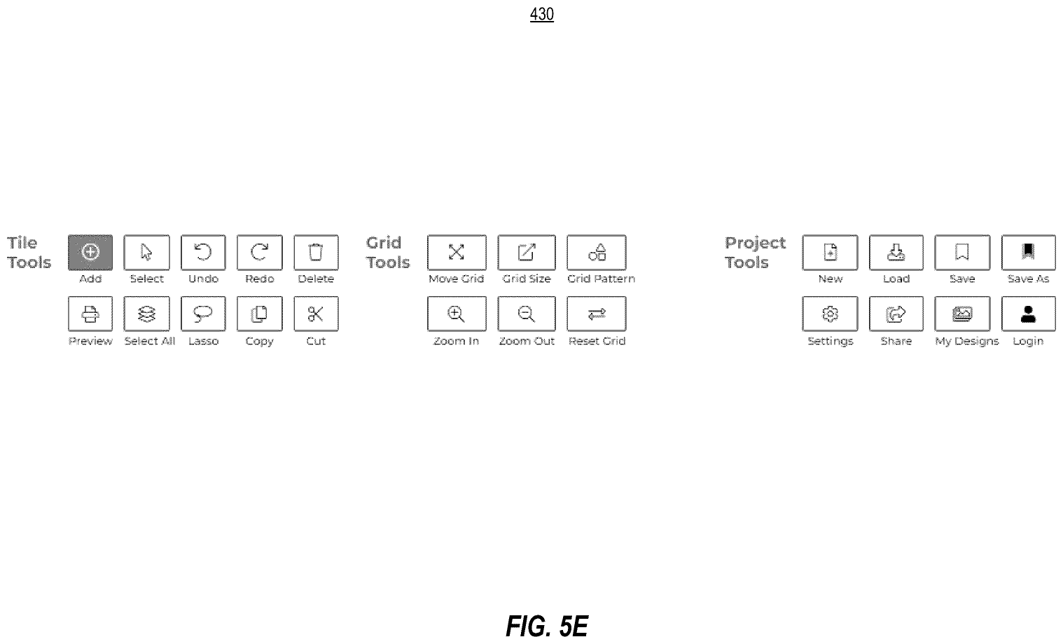

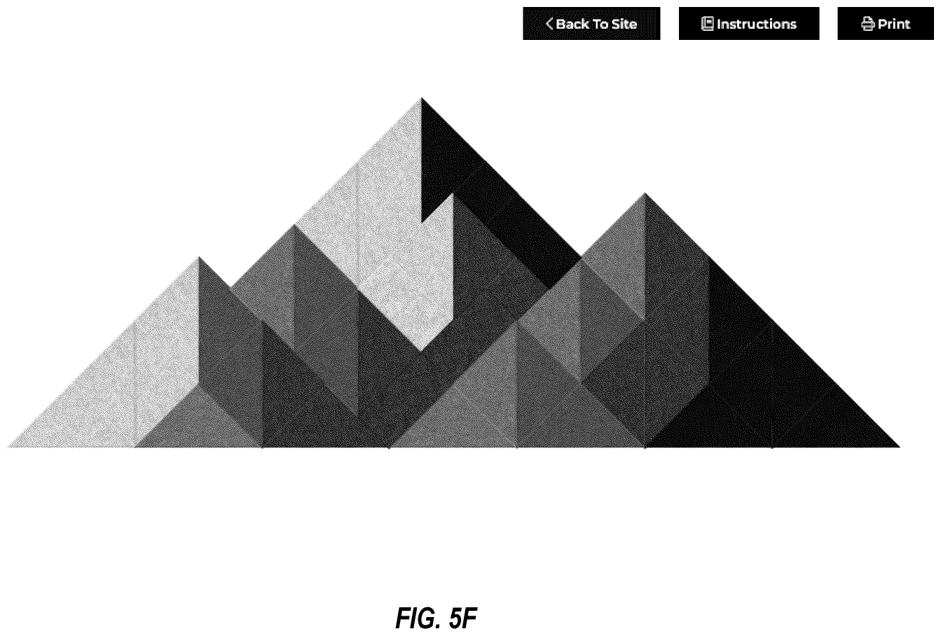

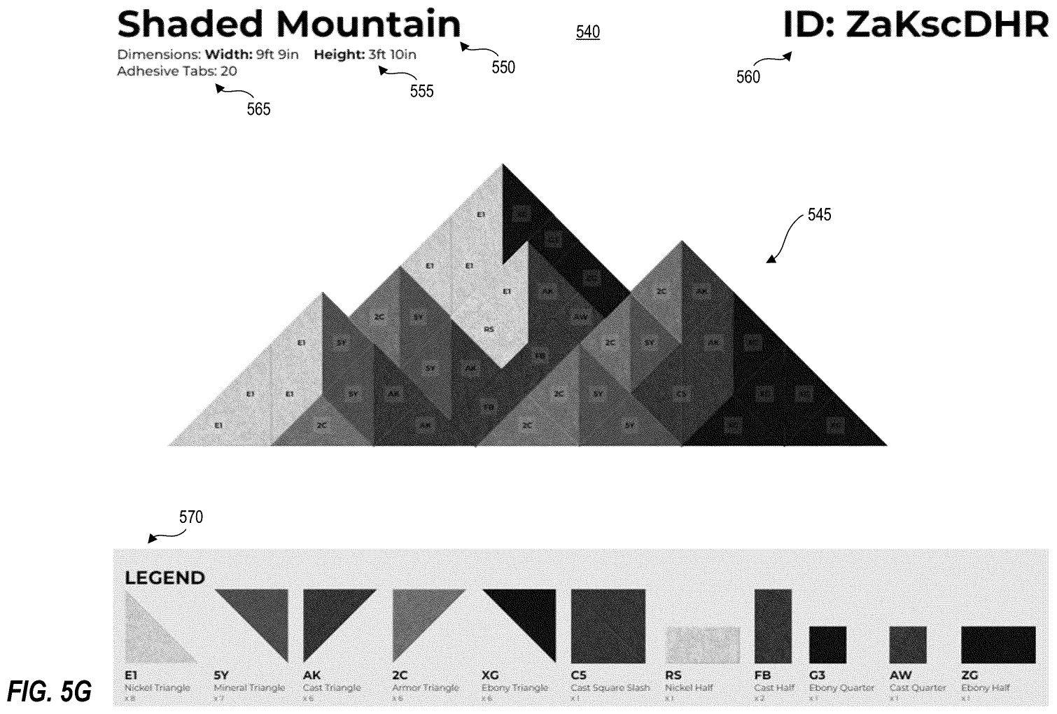

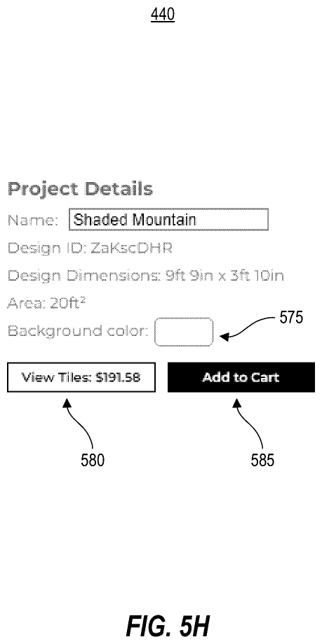

As illustrated in FIG. 4A, subarea 410 includes a “Shapes” section that includes various selectable elements associated with different decorative tile shapes. FIG. 5A provides a close-up representation of subarea 410 of design studio 400A. The “Shapes” section of subarea 410 includes various example decorative tile shapes that may be embodied by decorative tiles placed in the design area 470, such as, by way of non-limiting example, squares, rectangles, triangles, half circles, or quarter circles. In some implementations, the shapes represented in subarea 410 are associated with physical tile shapes that are available for purchase from a store and installation on walls of physical rooms. In this regard, the decorative tile shapes of subarea 410 can represent particular dimensions that correspond to real-world counterpart decorative tiles. For instance, the “Shapes” section of the subarea 410 of FIG. 5A can include a 23.75 inch×23.75 inch square, an 11.875 inch×11.875 inch square, a 5.94 inch×5.94 inch square, a 2.94 inch×2.94 inch square, a 23.75 inch×11.875 inch rectangle, a 5.94 inch×11.875 inch rectangle, a 23.75 inch×5.94 inch rectangle, a 2.94 inch×11.875 inch rectangle, an 11.875 inch×11.875 inch triangle, a 23.75 inch×11.875 inch half circle, a 5.875 inch×11.875 inch half circle, and an 11.875 inch×11.875 inch quarter circle. Other sizes/shapes are within the scope of the present disclosure, and the foregoing are provided by way of example only. In this way, when a user completes a decorative tile design using decorative tile shapes from the subarea 410 of the user selection area 480 of the design studio 400A, a user may order/purchase a physical set of decorative tiles that correspond to the decorative tile design and install the set of decorative tiles in a physical space, and the decorative tile design created by the user can serve as a basis for fulfilling the user's order.

In the example of FIG. 5A, the decorative tile shapes of the “Shapes” section are displayed with an orientation that corresponds to the orientation of the grid pattern of the design area 470 of the design studio 400A (see FIG. 4A). The decorative tile shapes of the “Shapes” section may be displayed with other orientations that correspond to different grid patterns of the design area 470.

In some implementations, a subarea 410 of a user selection area 480 of a design studio 400A can include additional or alternative types of shapes/tiles. For instance, FIG. 5B illustrates an additional subarea 505 that may be implemented in conjunction with a user selection area 480 of a design studio 400A. The additional subarea 505 of FIG. 5B includes additional selectable elements that correspond to decorative tiles that include engravings or patterns, such as a slash pattern (e.g., with a diagonal line across the decorative tile), a cross pattern (e.g., with two diagonal lines crossing the decorative tile), a 4-square pattern (e.g., with two crossing lines dividing the decorative tile into four equal squares or rectangles), a parallel pattern (e.g., with a plurality of parallel lines dividing the decorative tile into two or more parallel rectangles), and/or others. Engraved or patterned decorative tiles can be offered on different sizes and/or shapes of decorative tiles, such as on 23.75 inch×23.75 inch square decorative tiles, on 11.875 inch×11.875 inch square decorative tiles, and/or on others.

FIG. 5B provides an example of a design studio 400B that includes a design area 470B with a different type of grid pattern (i.e., a spaced hex grid pattern). FIG. 5B also illustrates a “Shapes” section of a subarea 410B of the design studio 400B that includes a different selection of shapes relative to the subarea 410 of the user selection area 480 of design studio 400A. For instance, subarea 410 of design studio 400B includes selectable elements corresponding to a 10.25 inch×11.75 inch hexagon and a 5.875 inch×10.25 inch parallelogram. In this regard, the decorative tile shapes of a user selection area of a design studio can be defined based on the grid type associated with the design area of the design studio. One will appreciate, in view of the present disclosure, that additional or alternative types of decorative tile shapes (relative to those shown and described with reference to FIGS. 4A, 4B, 5A, and 5B) can be included in a design studio, such as a 20.5 inch×11.75 inch parallelogram, or others.

Referring again to FIG. 4A, as noted above, the user selection area 480 of the design studio 400A can enable users to select the orientation of a decorative tile to be placed on the design area 470. In some implementations, orientation selection functionality is accessed within the subarea 410 of the user selection area 480. For instance, FIG. 5C illustrates a close-up representation of the subarea 410 of the user selection area 480 of the design studio 400A. In the example of FIG. 5C, user input has been directed to the triangle shape 510 shown with shading in FIG. 5C. Selection of the triangle shape, as shown in FIG. 5C, triggers display of selectable orientations 515 with which a triangular decorative tile may be placed in the design area 470. The user may then direct user input to one of the selectable orientations 515 to select an orientation. After making such a selection, the user may direct user input to the design area 470 of the design studio 400A to place a decorative tile in the design area 470 that embodies the selected orientation. Such functionality can enable users to rapidly configure and place decorative tiles in the design area 470 pursuant to creating a decorative tile design (e.g., rather than requiring users to place tiles in the design area 470 and then subsequently rotate each decorative tile after placement).

As illustrated in FIG. 4A, subarea 420 includes a “Colors” section that includes various selectable colors associated with different decorative tile colors. As indicated above, the colors available in the “Colors” section can correspond to colors available for physical decorative tiles that may be furnished based on a decorative tile design created via the design studio 400A (e.g., in response to placement of an order via the design studio 400A). FIG. 5D provides a close-up representation of subarea 420 of design studio 400A. In the example of FIG. 5D, the decorative tile colors of the “Colors” section include ebony, cast, mineral, armor, nickel, moon, zinc, latte, porcelain, cashmere, ash, timber, jasper, coral, raspberry, ruby, Aries, Moab, mustard, citrine, kiwi, aloe, sage, palm, Atlantic, aqua, baby blue, periwinkle, Cayman, slate blue, admiral, oxford, indigo, plum, lilac, and lavender. Each decorative tile color corresponds to a respective circular selectable element within the “Colors” section. Other decorative tile colors are within the scope of the present disclosure. A user may select a color prior to placement of a decorative tile within the design area 470 to cause the placed decorative tile to embody the selected color. Additionally, or alternatively, a user may select a decorative tile already placed in the design area 470 and subsequently select a color from the “Colors” section of subarea 420 to modify the color of the selected decorative tile.

As shown in FIG. 5D, the “Colors” section of subarea 420 of the user selection area 480 of design studio 400A also includes a “Select All” function 520. The “Select All” function 520 can enable users to rapidly modify colors of decorative tiles placed within the design area 470. In the example of FIG. 5D, the mineral color 525 from the “Colors” section has been selected via user input. In some instances, the user input selecting the mineral color 525 can be directed directly to the selectable element representing the mineral color 525 within the “Colors” section of the subarea 420, or can be directed to a decorative tile within the design area 470 that embodies the mineral color 525. With the mineral color 525 selected, subsequent selection of the “Select All” function 520 can cause selection of all decorative tiles within the design area 470 that embody the mineral color 525. The user can then subsequently select an update color from the “Colors” section to cause all decorative tiles within the design area 470 that previously embodied the mineral color 525 to take on the update color. The user can make additional or alternative modifications to the decorative tiles selected via the “Select All” function 520. Although the foregoing example has focused, in at least some respects, on selection of the mineral color 525, subsequent selection of all decorative tiles of the design area 470 that embody the mineral color 525 via the “Select All” function 520, and modification of the selected decorative tiles via further input directed to the user selection area 480, selection and/or modification on the basis of other colors may be performed in accordance with the disclosed subject matter.

As illustrated in FIG. 4A, subarea 430 includes a “Tile Tools” section, a “Grid Tools” section, and a “Project Tools” section. Each of the different sections of the subarea 430 include respective tools that may be used to facilitation various actions with respect to decorative tile designs. FIG. 5E provides a close-up representation of subarea 430 of design studio 400A. In the example of FIG. 5E, the “Tile Tools” section of the subarea 430 includes an “Add” function, a “Select” function, an “Undo” function, a “Redo” function, a “Delete” function, a “Preview” function, a “Select All” function, a “Lasso” function, a “Copy” function, and a “Cut” function. The “Add” function can enable users to add a decorative tile to the design area 470. For instance, with the “Add” function enabled, the user may direct user input to other subareas of the user selection area 480 (e.g., subareas 410 and/or 420) to select characteristics for a decorative tile and then direct user input to the design area 470 to add a decorative tile with the selected characteristics to the design area 470. The “Select” function can enable users to select decorative tiles already positioned within the design area 470. For instance, with the “Select” function enabled, the user may direct user input to a decorative tile within the design area 470 to select the decorative tile. The user may then direct additional user input to the design area 470 to reposition the selected decorative tile, or may direct additional user input to the user selection area 480 to modify characteristics of the selected decorative tile. The “Undo” function can enable users to undo an action previously performed (e.g., undo an addition of a decorative tile to the design area 470, undo a color change, undo a tile repositioning etc.). Conversely, the “Redo” function can enable users to redo a function that was previously undone. The “Delete” function can enable users to delete a decorative tile from the design area 470. The “Preview” function can provide users with a preview of decorative tile design represented in the design area 470 and/or can enable additional functionality (described hereinafter). The “Select All” function can enable users to select all decorative tiles within the design area 470 to effectuate global changes to all decorative tiles of a decorative tile design. The “Lasso” function can enable users to select multiple decorative tiles from the design area 470 by drawing a boundary that encompasses the decorative tiles for which selection is desired. The “Copy” function can enable users to copy a selected decorative tile from the design area 470 to a clipboard. A copied decorative tile can be pasted to create a copy of the decorative tile. The “Cut” function can enable users to copy a selected decorative tile from the design area 470 to a clipboard while removing the selected decorative tile from the design area 470.

In the example of FIG. 5E, the “Grid Tools” section of subarea 430 includes a “Move Grid” function, a “Grid Size” function, a “Grid Pattern” function, a “Zoom In” function, a “Zoom Out” function, and a “Reset Grid” function. The “Move Grid” function can enable users to reposition the depiction of the design area 470 within the design studio 400A. The “Grid Size” function can enable users to modify the physical dimensions to which the design area 470 corresponds. For instance, selection of the “Grid Size” function can resurface the “Canvas Dimensions” section of any of graphical user interfaces 300B, 300C, or 300D discussed hereinabove with reference to FIGS. 3B, 3C and 3D, respectively. The “Grid Pattern” function can enable users to modify the grid/pattern type of the design area 470. For instance, selection of the “Grid Pattern” function can resurface graphical user interface 300A, 300B, 300C, or 300D discussed hereinabove with reference to FIGS. 3A, 3B, 3C, and 3D, respectively. The “Zoom In” function can enable users to enlarge the representation of the design area 470 within the design studio 400A. The “Zoom Out” function can enable users to shrink the representation of the design area 470 within the design studio 400A. The “Reset Grid” function can enable users to reset the settings of the design area 470 to a previous or initial state.

In the example of FIG. 5E, the “Project Tools” section of subarea 430 includes a “New” function, a “Load” function, a “Save” function, a “Save As” function, a “Settings” function, a “Share” function, a “My Designs” function, and a “Login” function.

The “New” function can enable users to instantiate a new decorative tile design session/file. The “Load” function can enable users to load/access a previously saved decorative tile design session/file. The “Save” function can enable users to save the state of the decorative tile design represented in the design area 470 in the current session/file. The “Save As” function can enable users to save the state of the decorative tile design represented in the design area 470 to a new session/file. The “Settings” function can enable users to modify various aspects of the current decorative tile design session/file, such as the name of the current decorative tile design, whether the current decorative tile design is permitted to be published on a vendor website, an author name for the current decorative tile design, etc. The “Share” function can enable users to obtain a shareable link that can be copied and distributed to other users to enable the other users to access the current decorative tile design within a design studio 400A. The “My Designs” function can enable users to access a library of decorative tile designs associated with a user profile or account. The “Login” function can enable users to provide credentials to access a particular user profile or account.

FIG. 5F illustrates an example depiction of a preview 530 of the decorative tile design shown in the design area 470 of design studio 400A of FIG. 4A. In some implementations, the preview 530 can be accessed via the “Preview” function of the subarea 430 of the user selection area 480 of the design studio 400A. In the example of FIG. 5F, the preview 530 omits the grid background of the design area 470 and the elements of the user selection area 480 of the design studio 400A, which can allow the user to inspect various aspects of the decorative tile design prior to further action thereon. The preview 530 of FIG. 5F includes “Print” functionality, which may enable a system to send instructions to a printer to print a representation of the decorative tile design represented in the preview 530. The preview 530 of FIG. 5F also includes a “Back To Site” function that can enable users to return to the design studio 400A with the decorative tile design within the design area 470 of the design studio 400A.

The preview 530 of FIG. 5F also includes an “Instructions” function that can enable users to access an instruction sheet dynamically generated based on the decorative tile design. The instructions can be accessed in other ways, without limitation. FIG. 5G illustrates instructions 540 (e.g., a user instruction page) generated based on the decorative tile design shown in the preview 530 (and in the design area 470 of the design studio 400A of FIG. 4A). The instructions 540 can be dynamically generated based on a state of the decorative tile design within the design area 470 of a design studio 400A when an instructions function is selected. In some instances, the instructions 540 are continuously updated based on changes made to the decorative tile design within the design area 470 of the design studio 400A.

The instructions 540 of FIG. 5G includes various elements. The specific elements of the instructions 540 shown in FIG. 5G are provided by way of example only, and instructions generated based on a decorative tile design in accordance with the present disclosure can include additional or alternative elements. In the example of FIG. 5G, the instructions 540 includes a graphical representation of the decorative tile design 545. Each different type of decorative tile that forms the graphical representation of the decorative tile design 545 is associated with an identifier code. In the example of FIG. 5G, the identifier code of each decorative tile of the graphical representation of the decorative tile design 545 is displayed overlaid on the decorative tile (other modes of displaying the identifier codes in association with the decorative tiles are within the scope of the present disclosure). For instance, all decorative tiles of the graphical representation of the decorative tile design 545 that have a triangle shape, have a nickel color, and have a particular size are labeled in the graphical representation of the decorative tile design 545 with an “E1” identifier code overlaid thereon. The identifier code for each different type of decorative tile that forms the graphical representation of the decorative tile design 545 can be generated (e.g., randomly generated) pursuant to generation of the instructions 540. The identifier codes can enable users to distinguish between different types of decorative tiles that form the decorative tile design represented in the instructions 540.

The example instructions 540 of FIG. 5G also include other elements. For instance, the instructions 540 includes a name 550 of the decorative tile design (e.g., a user-defined name), dimensions 555 of the decorative tile design, a design identifier code 560 of the decorative tile design, and an adhesive tab quantity 565 for installing the decorative tile design within a physical room/space. The values represented in the dimensions 555, design identifier code 560, and/or the adhesive tab quantity 565 can be dynamically determined upon generation of the instructions 540 based on the decorative tile design created via the design studio 400A. The design identifier code 560 can be associated with a particular save session/file of the decorative tile design, such that other user profiles may enter the values represented in the design identifier code 560 to access a decorative tile design within a design studio 400A with characteristics identical to the decorative tile design for which the design identifier code 560 was generated.

The example instructions 540 of FIG. 5G also include a legend section 570 that can include various elements for interpreting the graphical representation of the decorative tile design 545 of the instructions 540. For instance, the legend section 570 of FIG. 5G includes a graphical representation of each different type of decorative tile represented in the decorative tile design. The legend section 570 also depicts the identifier code associated with each different type of decorative tile represented in the decorative tile design (e.g., “E1,” “5Y,” “AK,” “2C,” “XG,” “C5,” “RS,” “FB,” “G3,” “AW,” and “ZG” in FIG. 5G). The legend section 570 also includes the name of each different type of decorative tile represented in the decorative tile design (e.g., the name can include the color, the shape, and/or the engraving/pattern of each different type of decorative tile: “Nickel Triangle,” “Mineral Triangle,” “Cast Triangle,” “Armor Triangle,” “Ebony Triangle,” “Cast Square Slash,” “Nickel Half,” “Cast Half,” “Ebony Quarter,” “Cast Quarter,” and “Ebony Half” in FIG. 5G). The legend section 570 also includes the quantity of each different type of decorative tile represented in the decorative tile design (e.g., “x 8,” “x 7,” “x 6,” “x 6,” “x 6,” “x 1,” “x 1,” “x 2,” “x 1,” “x 1, ” and “x 1” in FIG. 5G).

The instructions 540 can be sent along with the decorative tiles for installing a decorative tile design in a physical space (e.g., in response to ordering of a decorative tile design created via a design studio 400A) to assist users with the installation process.

As illustrated in FIG. 4A, subarea 440 includes a “Project Details” section, which includes various information and/or functions related to the decorative tile design represented in the design area 470. FIG. 5H provides a close-up representation of subarea 440 of design studio 400A. In the example of FIG. 5H, the “Project Details” section includes the “Name” of the decorative tile design active within the design studio 400A. The “Name” field of the decorative tile design can be selectively editable by the user. The “Project Details” section of FIG. 5H also shows the “Design ID” of the decorative tile design, which corresponds to the design identifier code 560 discussed hereinabove with reference to FIG. 5G. The “Project Details section also includes the “Design Dimensions” of the decorative tile design, corresponding to the dimensions 555 discussed hereinabove with reference to FIG. 5G. In the example of FIG. 5H, the “Project Details” section also includes an “Area” of the decorative tile design, which may represent the wall coverage area of the decorative tiles that form the decorative tile design represented in the design area 470 of the design studio 400A.

The “Project Details” section of subarea 440 shown in FIG. 5H also includes a “Background color”, which may define a background color for the design area 470 over which decorative tiles are placed to create a decorative tile design. In some instances, a user may select a selectable element 575 to define the background color for the design area 470. In one example, a user may select a background color that substantially matches the wall color over which physical decorative tiles (corresponding to a decorative tile design created via the graphical user interface of the design studio 400A) are intended for installation.

The “Project Details” section of subarea 440 shown in FIG. 5H also includes other selectable elements, such as a “View Tiles” selectable element 580 and a “Add to Cart” selectable element 585. In the example of FIG. 5H, the “View Tiles” selectable element 580 displays a total price associated with the constituent decorative tiles of the decorative tile design represented in the design area 470 (the price of adhesives can also be included). Selection of the “View Tiles” selectable element 580 can trigger an itemized display of the different types of tiles that form the decorative tile design represented in the design area 470 (e.g., similar to the legend section 570 of the instructions 540 discussed hereinabove with reference to FIG. 5G). The “Add to Cart” selectable element 585 can add tiles for constructing the decorative tile design represented in the design area 470 to a virtual shopping cart to facilitate placement of an order for purchase of the tiles (and the adhesives, in some implementations). The order may be processed by one or more systems (e.g., server computing system 130, second client computing system 170, etc.) associated with a store, vendor, fulfillment center, third-party logistics provider, etc. to effectuate fulfillment and shipment of the order (e.g., by assembling a shipment that includes the tiles and/or adhesives that form the decorative tile design). The shipment can include the instructions 540, which can assist the user in installing the tiles to form the decorative tile design within a physical room/space.

In some instances, a system (e.g., server computing system 130, first client computing system 110, second client computing system 170, and/or other device) provides functionality for a user to determine a target coverage area for a decorative tile design. The target coverage area for the decorative tile design can enable the physical room in which the decorative tile design is installed to achieve desired acoustic and/or other characteristics. For instance, a decorative tile design can be constructed in a physical room/space using felt tiles, which can affect acoustic reverberation characteristics of the physical room/space. Such functionality can enable users to select and/or create a decorative tile design that provides aesthetic and functional benefits to the space in which the decorative tile design is installed.

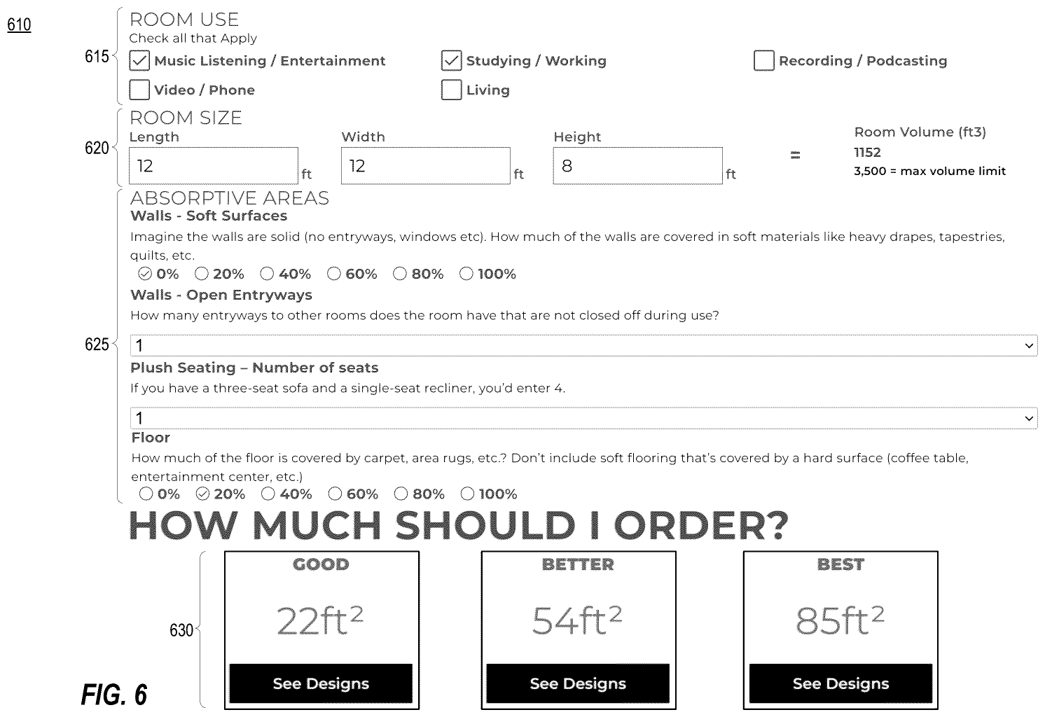

FIG. 6 depicts an example graphical user interface 610 associated with determining a target coverage area for a decorative tile design. The various elements shown in the graphical user interface 610 are provided by way of example only, and variations on the elements shown are within the scope of the present disclosure. The example graphical user interface 610 of FIG. 6 includes a room use prompt 615 that has a plurality of selectable room use options such as, by way of non-limiting example, “Music Listening/Entertainment,” “Studying/Working,” “Recording/Podcasting,” “Video/Phone,” and “Living.” A user may provide user input that selects one or more of the selectable room use options (e.g., by checking boxes in the example of FIG. 6). The selected room use options can correspond to intended use of a physical room in which the user intends to install a decorative tile design. As will be described in more detail hereinafter, the selected room use options can provide room use parameters usable to generate the target coverage area(s) for a decorative tile design.

The example graphical user interface 610 of FIG. 6 also includes a room size prompt 620 and an absorptive areas prompt 625 (or room characteristics prompt). The room size prompt 620 and the absorptive areas prompt 625 can enable the system to obtain (via user input) a set of room characteristics associated with the physical room in which the decorative tile design is intended for installation. The set of room characteristics can include various components, such as room size, existing soft surface coverage, open entryways, plush furniture characteristics, etc. As will be described in more detail hereinbelow, the set of room characteristics can provide an additional basis for generating the target coverage area(s) for a decorative tile design.

In the example of FIG. 6, the room size prompt 620 includes fields in which the user can enter a “Length,” a “Width,” and a “Height” for the physical room in which the decorative tile design is intended for installation. Based on the entered “Length,” “Width,” and “Height,” the volume of the room may be calculated and/or presented within the graphical user interface 610 (represented by the “Room Volume” section of the room size prompt 620).

In the example of FIG. 6, the absorptive areas prompt 625 includes a “Walls-Soft Surfaces” section, a “Walls-Open Entryways” section, a “Plush Seating-Number of Seats” section, and a “Floor” section. Users may provide user input at the various sections of the absorptive areas prompt 625 to provide room characteristics for the physical room in which the decorative tile design is intended for installation. For instance, the user may select or enter a percent coverage (e.g., “0%,” “20%,” “40%,” “60%,” “80%,” or “100%”) within the “Walls-Soft Surfaces” section to indicate the percentage of the walls within the physical space covered in soft materials, like heavy drapes, tapestries, quilts, etc. Although selectable percentages are used in the example of FIG. 6, other input modes are within the scope of the present disclosure (e.g., an entry field for entering a percentage value, selectable or enterable surface area values rather than percentages, etc.). As another example, the user may select or enter a quantity of open entryways within the “Walls-Open Entryways” section to indicate the quantity of open entryways within the physical space. An open entryway may correspond to a default area value. Although a quantity of open entryways is used in the example of FIG. 6, other input modes are within the scope of the present disclosure (e.g., selectable or enterable area values rather than a quantity of open entryways). As yet another example, the user may select or enter a quantity of plush seats within the “Plush Seating-Number of Seats” section to indicate the quantity of plush seats within the physical space. A plush seat can correspond to a default area/volume of absorptive material or a default unit effect on room reverberation. Although a quantity of plush seats is used in the example of FIG. 6, other input modes are within the scope of the present disclosure (e.g., selectable or enterable area or volume values in addition to or as an alternative to quantity). As an additional example, the user may select or enter a percent coverage (e.g., “0%,” “20%,” “40%,” “60%,” “80%,” or “100%”) within the “Floor” section to indicate the percentage of the floors within the physical space covered in soft materials, like carpet, area rugs, etc. Although selectable percentages are used in the example of FIG. 6, other input modes are within the scope of the present disclosure (e.g., an entry field for entering a percentage value, selectable or enterable surface area values rather than percentages, etc.).

Although, in the example of FIG. 6, the set of room characteristics is obtained via the room size prompt 620 and the absorptive areas prompt 625, the set of room characteristics can be obtained in other ways, such as by utilizing one or more sensor system associated with a user device (e.g., first client computing system 110). For instance, a user may be prompted to capture a video or one or more photos of a physical space, upon which computer vision techniques (e.g., simultaneous localization and mapping (SLAM), depth detection, object recognition/segmentation, and/or others) can be performed to determine the room size, existing soft surface coverage, open entryways, plush furniture characteristics, etc.

The system may utilize the room use parameter(s) and the set of room characteristics (e.g., obtained via the room size prompt 620 and the absorptive areas prompt 625) as inputs to generate one or more target coverage areas for a set of decorative tiles (e.g., a decorative tile design) installable within the physical room. For instance, in one example, the system determines one or more reverberation targets based on the room use parameter(s). Different reverberation time targets can be associated with different intended room uses. For example, the intended room use of “Recording/Podcasting” from the room use prompt 615 can be associated with a reverberation target within a range of about 0.3 s to about 0.7 s, whereas the intended room use of “Music Listening/Entertainment” can be associated with a reverberation target within a range of about 0.7 s to about 1.3 s. The reverberation target(s) associated with the selected room use parameter(s) (e.g., intended room use(s)) can be used in conjunction with the set of room characteristics to determine the target coverage area(s) for a decorative tile design for the physical room/space. In some implementations, when multiple intended room uses are selected via the room use prompt 615, the lowest reverberation target (or range of reverberation targets), or the highest reverberation target(s), or a combined, averaged, or aggregated reverberation target is selected for use in conjunction with the set of room characteristics to determine the target coverage area(s) for a decorative tile design for the physical room/space.

The reverberation target(s) (e.g., target reverberation times in RT60) associated with the room use parameter(s) (e.g., intended room use(s)) and the set of room characteristics (e.g., room volume, absorption of materials already present in the room, etc.) can be used to calculate the target coverage area(s) for a decorative tile design for the physical room/space, such as via the Sabine formula, the Eyring formula, the Norris-Eyring formula, the Fitzroy Robinson method, the Fitzmaurice method, and/or other technique. The system may then present the target coverage area(s) on a user interface. For instance, FIG. 6 illustrates an output section 630 that provides different target coverage areas based on the inputs provided in the room use prompt 615, the room size prompt 620, and the absorptive areas prompt 625. In the example of FIG. 6, multiple target coverage areas associated with different performance levels are provided, including a “Good” target coverage area of 22 ft\hat{ }2, a “Better” target coverage area of 54 ft\hat{ }2, and a “Best” target coverage area of 85 ft\hat{ }2. Each of the different target coverage areas presented in the graphical user interface 610 of FIG. 6 are presented in conjunction with a “See Designs” link that can facilitate presentation of recommended decorative tile design options that substantially achieve the associated target coverage area (e.g., that satisfy a threshold similarity to the associated target coverage area). The different target coverage areas can be determined based on different reverberation targets or ranges of reverberation targets for the physical room/space, or may be calculated as deviations from an initially calculated target coverage area from a single reverberation target or range of reverberation targets.

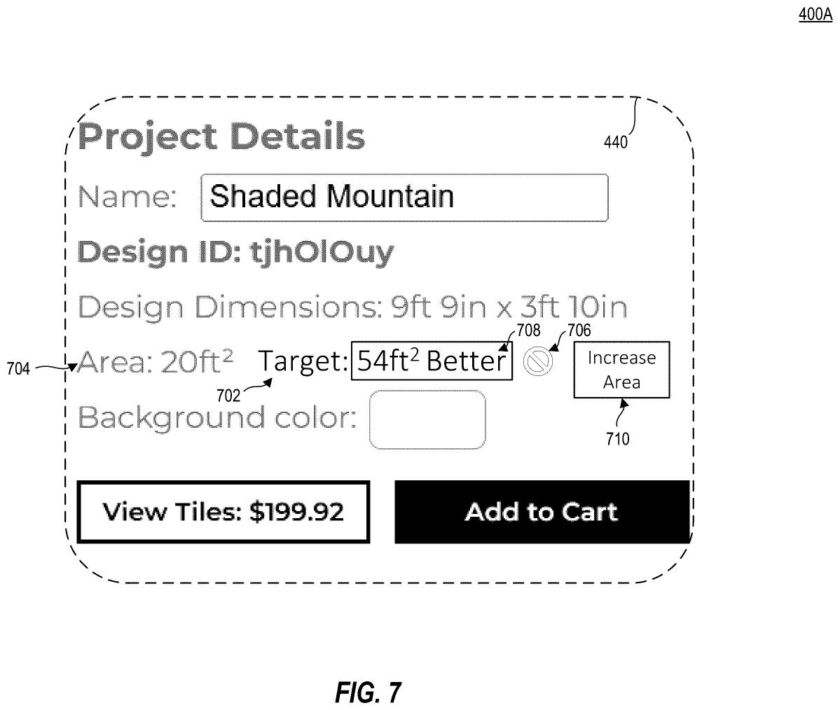

The target coverage area(s) calculated based on the room use parameter(s) and the set of room characteristics as described above can be presented in additional or alternative ways (relative to the example shown in FIG. 6). For example, the target coverage area(s) can be presented in conjunction with elements of a design studio 400A, such as by displaying an indication of whether the coverage area associated with a decorative tile design represented in the design area 470 of the design studio 400A (e.g., in the “Area” section of the “Project Details” section of the subarea 440 of the user selection area 480) satisfies the target coverage area(s). For instance, FIG. 7 provides a close-up representation of subarea 440 of design studio 400A from FIG. 4A with additional elements including a target coverage area(s) indicator 702 in proximity to the coverage area 704 of the current decorative tile design represented in the design area 470 (see FIG. 4A). The design studio 400A can additionally or alternatively include a “within range” indicator 706 or a performance level indicator 708 indicating whether the current coverage area will achieve “Good,” “Better,” or “Best” performance or another performance level (e.g., low or overperformance). The output label presented via the “within range” indicator 706 and/or the performance level indicator 708 can be selected based on a comparison of the coverage area 704 to the target coverage area(s) determined as described hereinabove with reference to FIG. 6 (e.g., by determining whether the coverage area 704 satisfies a threshold similarity to one or more target coverage areas). In some instances, the coverage area(s) indicator 702 and/or the performance level indicator 708 performance level indicator 708 indicates a performance level selected by a user. In some instances, the performance level indicator 708 indicates a performance level that can be achieved according to the current coverage area 704 of the current design shown in the design area 470. In some implementations, the design studio 400A can include recommendation output 710 that can recommend whether to increase or decrease the coverage area of the current decorative tile design to achieve a performance target (e.g., indicated by the target coverage area(s) indicator 702), and/or can include other types of output based on the relationship between the coverage area of the current decorative tile design and the target coverage area(s). Such functionality can enable users to easily create or modify a decorative tile design in accordance with desired functional performance (e.g., acoustic performance).

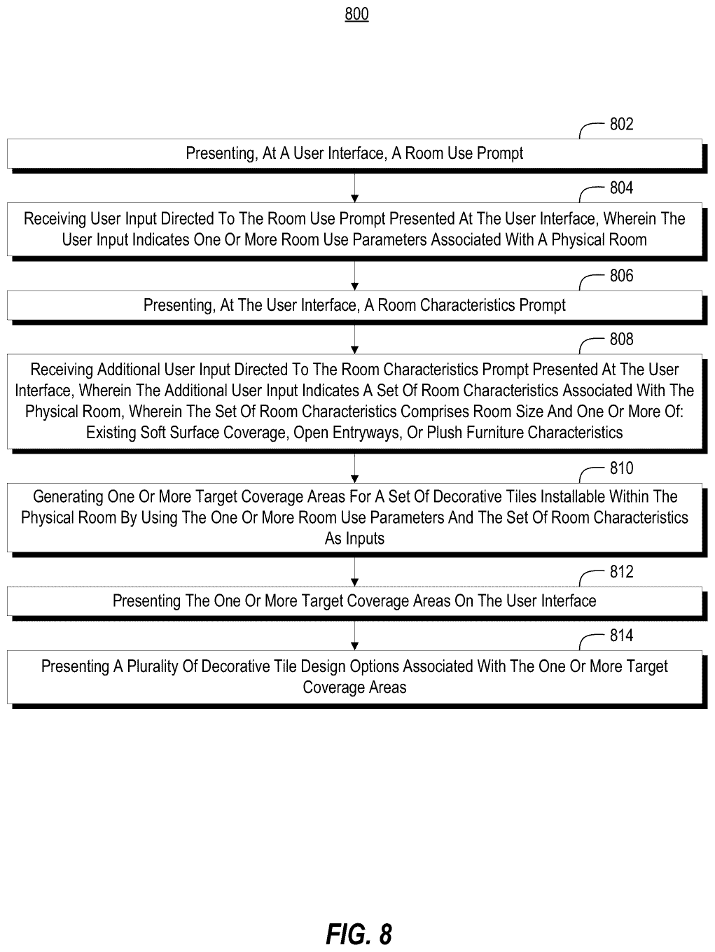

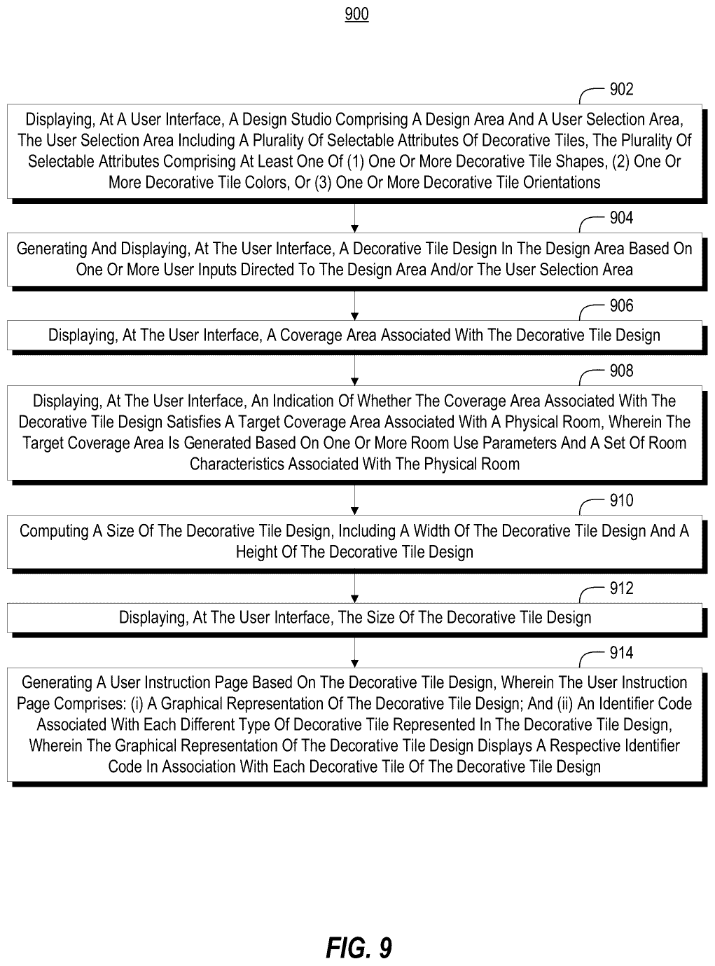

FIGS. 8 and 9 illustrate example flow diagrams depicting acts associated with the disclosed subject matter. Although the flow diagrams illustrate acts in a particular order, no specific ordering is required unless otherwise stated or unless performance of one act relies on completion of another. One or more of the acts shown and/or described in the flow diagrams may be omitted in some embodiments.

The acts described in association with the flow diagrams may be performed using one or more components of an environment 100 as described above. For instance, various acts may be performed using processor(s) 112 and/or 132, system memory(s) 114 and/or 134, storage device(s) 116 and/or 136, and/or other components of a client computing system 110 and/or 170, server computing system 130, or device connected to a network 160.

Act 802 of flow diagram 800 of FIG. 8 includes presenting, at a user interface, a room use prompt.

Act 804 of flow diagram 800 includes receiving user input directed to the room use prompt presented at the user interface, wherein the user input indicates one or more room use parameters associated with a physical room. In some instances, the room use prompt comprises a plurality of selectable room use options. In some implementations, the user input directed to the room use prompt comprises a user selection of one or more of the plurality of selectable room use options.

Act 806 of flow diagram 800 includes presenting, at the user interface, a room characteristics prompt.

Act 808 of flow diagram 800 includes receiving additional user input directed to the room characteristics prompt presented at the user interface, wherein the additional user input indicates a set of room characteristics associated with the physical room, wherein the set of room characteristics comprises room size and one or more of: existing soft surface coverage, open entryways, or plush furniture characteristics. In some examples, the set of room characteristics is obtained based at least in part on sensor data.

Act 810 of flow diagram 800 includes generating one or more target coverage areas for a set of decorative tiles installable within the physical room by using the one or more room use parameters and the set of room characteristics as inputs. In some embodiments, the one or more target coverage areas comprise a plurality of different target coverage areas associated with different performance levels. In some instances, generating the one or more target coverage areas comprises: (i) determining one or more reverberation targets based on the one or more room use parameters; and (ii) utilizing the one or more reverberation targets in conjunction with the set of room characteristics to determine the one or more target coverage areas.

Act 812 of flow diagram 800 includes presenting the one or more target coverage areas on the user interface. In some implementations, presenting the one or more target coverage areas on the user interface comprises presenting the one or more target coverage areas in conjunction with a design studio presented at the user interface, where the design studio comprises a design area and a user selection area, and where the user selection area comprises a plurality of selectable attributes of decorative tiles, the plurality of selectable attributes comprising at least one of (1) one or more decorative tile shapes, (2) one or more decorative tile colors, or (3) one or more decorative tile orientations.

Act 814 of flow diagram 800 includes presenting a plurality of decorative tile design options associated with the one or more target coverage areas.

Act 902 of flow diagram 900 of FIG. 9 includes displaying, at a user interface, a design studio comprising a design area and a user selection area, the user selection area including a plurality of selectable attributes of decorative tiles, the plurality of selectable attributes comprising at least one of (1) one or more decorative tile shapes, (2) one or more decorative tile colors, or (3) one or more decorative tile orientations. In some examples, the one or more decorative tile shapes of the user selection area are defined based on a grid type associated with the design area. In some embodiments, the one or more decorative tile shapes include one or more of: (i) a 23.75 inch×23.75 inch square, (ii) an 11.875 inch×11.875 inch square, (iii) a 5.94 inch×5.94 inch square, (iv) a 2.94 inch×2.94 inch square, (v) a 23.75 inch×11.875 inch rectangle, (vi) a 5.94 inch×11.875 inch rectangle, (vii) a 23.75 inch×5.94 inch rectangle, (viii) a 2.94 inch× 11.875 inch rectangle, (ix) an 11.875 inch×11.875 inch triangle, (x) a 10.25 inch×11.75 inch×hexagon, (xi) a 20.5 inch×11.75 inch parallelogram, (xii) a 5.875 inch×10.25 inch parallelogram, (xiii) a 23.75 inch×11.875 inch half circle, (xiv) a 5.875 inch×11.875 inch half circle, or (xv) an 11.875 inch×11.875 inch quarter circle. In some instances, the 23.75 inch×23.75 inch square or the 11.875 inch×11.875 inch square comprises one or more engravings.

Act 904 of flow diagram 900 includes generating and displaying, at the user interface, a decorative tile design in the design area based on one or more user inputs directed to the design area and/or the user selection area. In some implementations, generating and displaying the decorative tile design comprises: (i) receiving a first user input, selecting at least one attribute of the plurality of selectable attributes of decorative tiles from the user selection area; (ii) receiving a second user input, placing a decorative tile comprising the selected at least one attribute at a particular position of the design area; and (iii) repeating steps (i) and (ii) until the decorative tile design is completed. In some instances, generating and displaying the decorative design tile further comprises: (iv) receiving a third user input selecting a particular decorative tile placed in the design area; (v) receiving a fourth user input selecting or modifying at least one of the plurality of selectable attributes of decorative tiles associated with the particular decorative tile; and (vi) changing one or more attributes of the particular decorative tile based on the at least one of the plurality of selectable attributes of decorative tiles selected or modified via the fourth user input. In some examples, in at least one repetition of step (i) of act 904, selecting the one or more decorative tile orientations comprises: (1) receiving user input selecting a decorative tile shape of the one or more decorative tile shapes to trigger display of a plurality of decorative tile orientations of the one or more decorative tile orientations for the decorative tile shape; and (2) receiving user input selecting a decorative tile orientation of the plurality of decorative tile orientations. In some embodiments, placing the decorative tile comprising the selected at least one attribute at the particular position of the design area comprises: (a) identifying a grid or a fraction of a grid of the design area that is closest to the particular position indicated by the second user input; and (b) snapping the decorative tile to the identified grid or the identified fraction of the grid in the design area.

Act 906 of flow diagram 900 includes displaying, at the user interface, a coverage area associated with the decorative tile design.

Act 908 of flow diagram 900 includes displaying, at the user interface, an indication of whether the coverage area associated with the decorative tile design satisfies a target coverage area associated with a physical room, wherein the target coverage area is generated based on one or more room use parameters and a set of room characteristics associated with the physical room.

Act 910 of flow diagram 900 includes computing a size of the decorative tile design, including a width of the decorative tile design and a height of the decorative tile design.

Act 912 of flow diagram 900 includes displaying, at the user interface, the size of the decorative tile design.

Act 914 of flow diagram 900 includes generating a user instruction page based on the decorative tile design, wherein the user instruction page comprises: (i) a graphical representation of the decorative tile design; and (ii) an identifier code associated with each different type of decorative tile represented in the decorative tile design, wherein the graphical representation of the decorative tile design displays a respective identifier code in association with each decorative tile of the decorative tile design. In some instances, the user instruction page further comprises one or more of: (1) a legend section comprising one or more of: (a) a graphical representation of each different type of decorative tile represented in the decorative tile design; (b) the identifier code associated with each different type of decorative tile represented in the decorative tile design; (c) a name of each different type of decorative tile represented in the decorative tile design; and (d) a quantity of each different type of decorative tile represented in the decorative tile design; (2) a name of the decorative tile design; (3) one or more dimensions of the decorative tile design; (4) a design identifier code associated with the decorative tile design; and (5) a quantity of adhesive tabs usable to install decorative tiles forming the decorative tile design in the physical room. In some implementations, the quantity of adhesive tabs is automatically generated based on the decorative tile design.

Although the subject matter has been described in language specific to structural features and/or methodological acts, it is to be understood that the subject matter defined in the appended claims is not necessarily limited to the described features or acts described above, or the order of the acts described above. Rather, the described features and acts are disclosed as example forms of implementing the claims.

The present invention may comprise or utilize a special-purpose or general-purpose computer system that includes computer hardware, such as, for example, one or more processors and system memory, as discussed in greater detail below. Embodiments within the scope of the present invention also include physical and other computer-readable media for carrying or storing computer-executable instructions and/or data structures. Such computer-readable media can be any available media that can be accessed by a general-purpose or special-purpose computer system. Computer-readable media that store computer-executable instructions and/or data structures are computer storage media. Computer-readable media that carry computer-executable instructions and/or data structures are transmission media. Thus, by way of example, and not limitation, embodiments of the invention can comprise at least two distinctly different kinds of computer-readable media: computer storage media and transmission media.

Computer storage media are physical storage media that store computer-executable instructions and/or data structures. Physical storage media include computer hardware, such as RAM, ROM, EEPROM, solid state drives (“SSDs”), flash memory, phase-change memory (“PCM”), optical disk storage, magnetic disk storage or other magnetic storage devices, or any other hardware storage device(s) which can be used to store program code in the form of computer-executable instructions or data structures, which can be accessed and executed by a general-purpose or special-purpose computer system to implement the disclosed functionality of the invention.

Transmission media can include a network and/or data links which can be used to carry program code in the form of computer-executable instructions or data structures, and which can be accessed by a general-purpose or special-purpose computer system. A “network” is defined as one or more data links that enable the transport of electronic data between computer systems and/or modules and/or other electronic devices. When information is transferred or provided over a network or another communications connection (either hardwired, wireless, or a combination of hardwired or wireless) to a computer system, the computer system may view the connection as transmission media. Combinations of the above should also be included within the scope of computer-readable media.

Further, upon reaching various computer system components, program code in the form of computer-executable instructions or data structures can be transferred automatically from transmission media to computer storage media (or vice versa). For example, computer-executable instructions or data structures received over a network or data link can be buffered in RAM within a network interface module (e.g., a “NIC”), and then eventually transferred to computer system RAM and/or to less volatile computer storage media at a computer system. Thus, it should be understood that computer storage media can be included in computer system components that also (or even primarily) utilize transmission media.

Computer-executable instructions comprise, for example, instructions and data which, when executed at one or more processors, cause a general-purpose computer system, special-purpose computer system, or special-purpose processing device to perform a certain function or group of functions. Computer-executable instructions may be, for example, binaries, intermediate format instructions such as assembly language, or even source code.

Those skilled in the art will appreciate that the invention may be practiced in network computing environments with many types of computer system configurations, including, personal computers, desktop computers, laptop computers, message processors, hand-held devices, multi-processor systems, microprocessor-based or programmable consumer electronics, network PCs, minicomputers, mainframe computers, mobile telephones, PDAs, tablets, pagers, routers, switches, and the like. The invention may also be practiced in distributed system environments where local and remote computer systems, which are linked (either by hardwired data links, wireless data links, or by a combination of hardwired and wireless data links) through a network, both perform tasks. As such, in a distributed system environment, a computer system may include a plurality of constituent computer systems. In a distributed system environment, program modules may be located in both local and remote memory storage devices.

Those skilled in the art will also appreciate that the invention may be practiced in a cloud-computing environment. Cloud computing environments may be distributed, although this is not required. When distributed, cloud computing environments may be distributed internationally within an organization and/or have components possessed across multiple organizations. In this description and the following claims, “cloud computing” is defined as a model for enabling on-demand network access to a shared pool of configurable computing resources (e.g., networks, servers, storage, applications, and services). The definition of “cloud computing” is not limited to any of the other numerous advantages that can be obtained from such a model when properly deployed.

A cloud-computing model can be composed of various characteristics, such as on-demand self-service, broad network access, resource pooling, rapid elasticity, measured service, and so forth. A cloud-computing model may also come in the form of various service models such as, for example, Software as a Service (“SaaS”), Platform as a Service (“PaaS”), and Infrastructure as a Service (“IaaS”). The cloud-computing model may also be deployed using different deployment models such as private cloud, community cloud, public cloud, hybrid cloud, and so forth.

Some embodiments, such as a cloud-computing environment, may comprise a system that includes one or more hosts that are each capable of running one or more virtual machines. During operation, virtual machines emulate an operational computing system, supporting an operating system and perhaps one or more other applications as well. In some embodiments, each host includes a hypervisor that emulates virtual resources for the virtual machines using physical resources that are abstracted from view of the virtual machines. The hypervisor also provides proper isolation between the virtual machines. Thus, from the perspective of any given virtual machine, the hypervisor provides the illusion that the virtual machine is interfacing with a physical resource, even though the virtual machine only interfaces with the appearance (e.g., a virtual resource) of a physical resource. Examples of physical resources including processing capacity, memory, disk space, network bandwidth, media drives, and so forth.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A system for determining decorative tile configurations, the system comprising:
one or more processors; and
one or more computer-readable recording media that store instructions that are executable by the one or more processors to configure the system to:
present, at a user interface, a room use prompt;
receive user input directed to the room use prompt presented at the user interface, wherein the user input indicates one or more room use parameters associated with a physical room;
present, at the user interface, a room characteristics prompt;
receive additional user input directed to the room characteristics prompt presented at the user interface, wherein the additional user input indicates a set of room characteristics associated with the physical room, wherein the set of room characteristics comprises room size and one or more of: existing soft surface coverage, open entryways, or plush furniture characteristics;
generate one or more target coverage areas for a set of decorative tiles installable within the physical room by using the one or more room use parameters and the set of room characteristics as inputs; and
present the one or more target coverage areas on the user interface.

2. The system of claim 1, wherein the one or more target coverage areas comprise a plurality of different target coverage areas associated with different performance levels.

3. The system of claim 1, wherein the room use prompt comprises a plurality of selectable room use options, and wherein the user input directed to the room use prompt comprises a user selection of one or more of the plurality of selectable room use options.

4. The system of claim 1, wherein the set of room characteristics is obtained based at least in part on sensor data.

5. The system of claim 1, wherein the instructions are executable by the one or more processors to further configure the system to present a plurality of decorative tile design options associated with the one or more target coverage areas.

6. The system of claim 1, wherein generating the one or more target coverage areas comprises:
determining one or more reverberation targets based on the one or more room use parameters; and
utilizing the one or more reverberation targets in conjunction with the set of room characteristics to determine the one or more target coverage areas.

7. The system of claim 1, wherein presenting the one or more target coverage areas on the user interface comprises presenting the one or more target coverage areas in conjunction with a design studio presented at the user interface, wherein the design studio comprises a design area and a user selection area, and wherein the user selection area comprises a plurality of selectable attributes of decorative tiles, the plurality of selectable attributes comprising at least one of (1) one or more decorative tile shapes, (2) one or more decorative tile colors, or (3) one or more decorative tile orientations.

8. A system for determining decorative tile configurations, the system comprising:
one or more processors; and
one or more computer-readable recording media that store instructions that are executable by the one or more processors to configure the system to:
display, at a user interface, a design studio comprising a design area and a user selection area, the user selection area including a plurality of selectable attributes of decorative tiles, the plurality of selectable attributes comprising at least one of (1) one or more decorative tile shapes, (2) one or more decorative tile colors, or (3) one or more decorative tile orientations;
generate and display, at the user interface, a decorative tile design in the design area based on one or more user inputs directed to the design area and/or the user selection area;
display, at the user interface, a coverage area associated with the decorative tile design; and
display, at the user interface, an indication of whether the coverage area associated with the decorative tile design satisfies a target coverage area associated with a physical room, wherein the target coverage area is generated based on one or more room use parameters and a set of room characteristics associated with the physical room.

9. The system of claim 8, wherein generating and displaying the decorative tile design comprises:
(i) receiving a first user input selecting at least one attribute of the plurality of selectable attributes of decorative tiles from the user selection area;
(ii) receiving a second user input placing a decorative tile comprising the selected at least one attribute at a particular position of the design area; and
(iii) repeating steps (i) and (ii) until the decorative tile design is completed.

10. The system of claim 9, wherein, in at least one repetition of step (i), selecting the one or more decorative tile orientations comprises:
receiving user input selecting a decorative tile shape of the one or more decorative tile shapes to trigger display of a plurality of decorative tile orientations of the one or more decorative tile orientations for the decorative tile shape; and
receiving user input selecting a decorative tile orientation of the plurality of decorative tile orientations.

11. The system of claim 9, wherein placing the decorative tile comprising the selected at least one attribute at the particular position of the design area comprises:
(a) identifying a grid or a fraction of a grid of the design area that is closest to the particular position indicated by the second user input; and
(b) snapping the decorative tile to the identified grid or the identified fraction of the grid in the design area.

12. The system of claim 9, wherein generating and displaying the decorative design tile further comprises:
receiving a third user input selecting a particular decorative tile placed in the design area;
receiving a fourth user input selecting or modifying at least one of the plurality of selectable attributes of decorative tiles associated with the particular decorative tile; and
changing one or more attributes of the particular decorative tile based on the at least one of the plurality of selectable attributes of decorative tiles selected or modified via the fourth user input.

13. The system of claim 8, wherein the instructions are executable by the one or more processors to further configure the system to:
compute a size of the decorative tile design, including a width of the decorative tile design and a height of the decorative tile design; and
display, at the user interface, the size of the decorative tile design.

14. The system of claim 8, wherein the one or more decorative tile shapes include one or more of:
(i) a 23.75 inch×23.75 inch square,
(ii) an 11.875 inch×11.875 inch square,
(iii) a 5.94 inch×5.94 inch square,
(iv) a 2.94 inch×2.94 inch square,
(v) a 23.75 inch×11.875 inch rectangle,
(vi) a 5.94 inch×11.875 inch rectangle,
(vii) a 23.75 inch×5.94 inch rectangle,
(viii) a 2.94 inch×11.875 inch rectangle,
(ix) an 11.875 inch×11.875 inch triangle,
(x) a 10.25 inch×11.75 inch hexagon,
(xi) a 20.5 inch×11.75 inch parallelogram,
(xii) a 5.875 inch×10.25 inch parallelogram,
(xiii) a 23.75 inch×11.875 inch half circle,
(xiv) a 5.875 inch×11.875 inch half circle, or
(xv) an 11.875 inch×11.875 inch quarter circle.

15. The system of claim 14, wherein the 23.75 inch×23.75 inch square or the 11.875 inch×11.875 inch square comprises one or more engravings.

16. The system of claim 8, wherein the instructions are executable by the one or more processors to further configure the system to:
generate a user instruction page based on the decorative tile design, wherein the user instruction page comprises:
a graphical representation of the decorative tile design; and
an identifier code associated with each different type of decorative tile represented in the decorative tile design, wherein the graphical representation of the decorative tile design displays a respective identifier code in association with each decorative tile of the decorative tile design.

17. The system of claim 16, wherein the user instruction page further comprises one or more of:
a legend section comprising one or more of:
a graphical representation of each different type of decorative tile represented in the decorative tile design;
the identifier code associated with each different type of decorative tile represented in the decorative tile design;
a name of each different type of decorative tile represented in the decorative tile design; and
a quantity of each different type of decorative tile represented in the decorative tile design;
a name of the decorative tile design;
one or more dimensions of the decorative tile design;
a design identifier code associated with the decorative tile design; and
a quantity of adhesive tabs usable to install decorative tiles forming the decorative tile design in the physical room.

18. The system of claim 17, wherein the quantity of adhesive tabs is automatically generated based on the decorative tile design.

19. The system of claim 8, wherein the one or more decorative tile shapes of the user selection area are defined based on a grid type associated with the design area.

20. A method for determining decorative tile configurations, the method comprising:
presenting, at a user interface, a room use prompt;
receiving user input directed to the room use prompt presented at the user interface, wherein the user input indicates one or more room use parameters associated with a physical room;
presenting, at the user interface, a room characteristics prompt;
receiving additional user input directed to the room characteristics prompt presented at the user interface, wherein the additional user input indicates a set of room characteristics associated with the physical room, wherein the set of room characteristics comprises room size and one or more of: existing soft surface coverage, open entryways, or plush furniture characteristics;
generating one or more target coverage areas for a set of decorative tiles installable within the physical room by using the one or more room use parameters and the set of room characteristics as inputs; and
presenting the one or more target coverage areas on the user interface.
